(19) United States
(12) Patent Application Publication
(10) Pub. No.: US 2021/0091537 A1
(43) Pub. Date: Mar. 25, 2021

(54) HIGH-POWER VERTICAL CAVITY SURFACE EMITTING LASER DIODE (VCSEL)

(71) Applicant: VISUAL PHOTONICS EPITAXY CO., LTD., Taoyuan City (TW)

(72) Inventors: Chao-Hsing Huang, Taoyuan City (TW); Yu-Chung Chin, Taoyuan City (TW); Van-Truong Dai, Vinhphuc province (VN)

(21) Appl. No.: 17/029,177

(22) Filed: Sep. 23, 2020

(30) Foreign Application Priority Data
Sep. 24, 2019 (TW) 108134357

(51) Int. Cl. H01S 5/183

(52) U.S. Cl. CPC H01S 5/18305; H01S 5/32; H01S 5/18311

(57) ABSTRACT

Provided is a high-power vertical cavity surface emitting laser diode (VCSEL), including a first epitaxial region, an active region and a second epitaxial region. One of the first epitaxial region and the second epitaxial region is an N-type epitaxial region, and the other of the first epitaxial region and the second epitaxial region includes a PN junction. The PN junction includes a P-type epitaxial layer, a tunnel junction and an N-type epitaxial layer. The tunnel junction is located between the P-type epitaxial layer and the N-type epitaxial layer, and the P-type epitaxial layer of the PN junction is closest to the active region.

### CROSS-REFERENCE TO RELATED APPLICATION

This application claims priority to Taiwanese Application Serial No.

108134357, filed on Sep. 24, 2019. The entirety of the above-mentioned patent application is hereby incorporated by reference herein.

### TECHNICAL FIELD

The technical field relates to a vertical cavity surface emitting layer diode (VCSEL), especially a high-power VCSEL with a PN junction for applications such as distance sensing, 3D sensing, LiDAR and infrared lighting.

### BACKGROUND

A vertical cavity surface emitting layer diode (VCSEL) is a type of laser element, which can be used as a light source for 3D sensing, optical communications or infrared lighting. According to the direction in which the laser light is emitted, the VCSEL can be divided into a top-emitting type (the total reflectivity of the upper DBR layer is less than that of the lower DBR layer) and a bottom-emitting type (the total reflectivity of the upper DBR layer is greater than that of the lower DBR layer).

The VCSEL is formed by epitaxially growing a multi-layer structure on a substrate, and the multi-layer structure includes a lower epitaxial region, an active region and an upper epitaxial region.

Referring to FIG. 1, the lower epitaxial region includes a lower DBR layer 20′ and a lower spacer layer 30′, and the upper epitaxial region includes an upper spacer layer 34′ and an upper DBR layer 40′. The active region 32′ is between the lower epitaxial region and the upper epitaxial region. The lower epitaxial region and the upper epitaxial region have multiple N-type epitaxial layers and multiple P-type epitaxial layers, respectively, or have multiple P-type epitaxial layers and multiple N-type epitaxial layers, respectively. The number of the lower DBR layers 20′ or the number of the upper DBR layers 40′ is usually as many as tens.

The majority carriers of the P-type epitaxial layer and the N-type epitaxial layer are holes and electrons, respectively. Since the effective mass of hole is larger than that of electron and the mobility of hole is lower than that of electron, the resistance of the material of the P-type epitaxial layer is not only larger than that of the N-type epitaxial layer, but thermal conductivity of the P-type epitaxial layer is also worse than that of the N-type epitaxial layer. In addition, due to the high resistance of the material of the P-type epitaxial layer, current is not easy to spread uniformly when passing through the P-type epitaxial layer.

When the doping concentration of the P-type epitaxial layer and the N-type epitaxial layer are the same, the P-type epitaxial layer has more light absorption than the N-type epitaxial layer. Since the P-type epitaxial layer absorbs more light, in addition to reducing the light output performance of the active region, the temperature of the P-type epitaxial layer is easily increased due to the absorption of light energy.

When dozens of layers in the lower (upper) DBR layer are all P-type epitaxial layers, the overall resistance in the lower (upper) DBR layer 20′ is too large, and the large resistance means that the power loss is also large such that the output power and performance of VCSEL are easily limited or even attenuated.

Further, since the current is not easy to be evenly distributed when the current passes through dozens of P-type epitaxial layers, the divergence of the laser beam emitted by the VCSEL will be larger, or the beam profile of the laser beam of the VCSEL is not close to the required beam profile.

When the number of the P-type epitaxial layers is greater, the P-type epitaxial layers will absorb more light. Therefore, when the VCSEL is working, the temperature of the P-type lower (upper) DBR layer is likely to be high, and the P-type epitaxial layers have poor thermal conductivity such that it is difficult to dissipate the thermal energy in the active region. Consequently, when the VCSEL is operating, the temperature of the active region is difficult to drop and is relatively high such that the output power and performance of the VCSEL is limited.

In the lower (upper) epitaxial region, an epitaxial layer other than the DBR layer is usually arranged, or the number of active layers and the number of other epitaxial layers are increased in the active region so as to improve or enhance the performance of the VCSEL. However, in the prior art, the epitaxial layers arranged in the P-type lower (upper) epitaxial region may be P-type doped or undoped epitaxial layers. Accordingly, the resistance or light absorption of the P-type lower (upper) epitaxial region is likely to increase. Moreover, when the number of stacked P-type epitaxial layers above or below the active region is greater, the temperature of the active region may be more difficult to reduce. As such, if an epitaxial layer other than the DBR layer is arranged in the lower (upper) epitaxial region, the output power and performance of the VCSEL may be further reduced.

### SUMMARY

In one embodiment, provided is a high-power VCSEL, mainly including an N-type first epitaxial region, an active region and a second epitaxial region. The N-type first epitaxial region is located on a substrate. The active region is located on the N-type first epitaxial region. The active region includes one or more active layers. The second epitaxial region is located on the active region. The second epitaxial region includes a PN junction. The PN junction includes at least one P-type epitaxial layer, a tunnel junction and at least one N-type epitaxial layer. The tunnel junction is located between the at least one P-type epitaxial layer and the at least one N-type epitaxial layer. The at least one P-type epitaxial layer is close to the active region, and the at least one P-type epitaxial layer is between the at least one N-type epitaxial layer and the active region.

In one embodiment, provided is a high-power VCSEL, including a first epitaxial region, an active region and an N-type second epitaxial region. The first epitaxial region is located on a substrate, and includes a PN junction. The PN junction includes at least one P-type epitaxial layer, a tunnel junction and at least one N-type epitaxial layer. The tunnel junction is located between the at least one P-type epitaxial layer and the at least one N-type epitaxial layer. The active region is located on the first epitaxial region, and includes one or more active layers. The N-type second epitaxial region is located on the active region. The at least one P-type epitaxial layer is close to the active region, and the at least one N-type epitaxial layer is close to the substrate.

### BRIEF DESCRIPTION OF THE DRAWINGS

FIG. 1 is a schematic diagram of a conventional VCSEL.

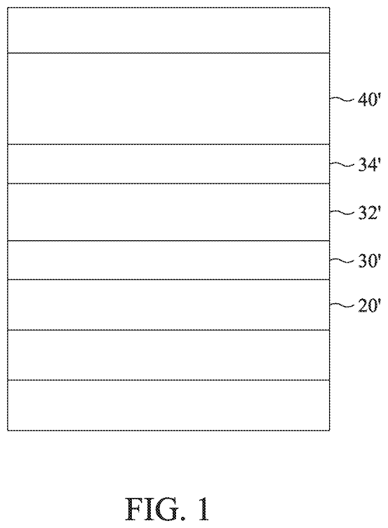

FIG. 2 is a schematic diagram of a PN junction disposed on an upper DBR layer of a VCSEL according to one embodiment of the present disclosure.

FIG. 3 is a schematic diagram showing a PN junction disposed on a first upper spacer layer of a VCSEL according to one embodiment of the present disclosure, wherein the first upper spacer layer is located between an active layer and an oxidation layer.

FIG. 4 is a schematic diagram showing a PN junction disposed on a second upper spacer layer of a VCSEL according to a preferred embodiment of the present disclosure, wherein the PN junction is located between an upper DBR layer and an oxidation layer.

FIG. 5 is a schematic diagram of a PN junction disposed in a lower DBR layer of a VCSEL according to one embodiment of the present disclosure.

FIG. 6 is a schematic diagram of a PN junction disposed in a first lower spacer layer of a VCSEL according to one embodiment of the present disclosure, wherein the first lower spacer layer is located between an active layer and an oxidation layer.

FIG. 7 is a schematic diagram of an epitaxial conversion structure disposed in the second lower spacer layer of a VCSEL according to one embodiment of the present disclosure, wherein the second lower spacer layer is located between a lower DBR layer and an oxidation layer.

FIG. 8 is a schematic diagram of a VCSEL with an active region including two active layers according to one embodiment of the present disclosure.

FIG. 9 is a L-I-V curve of the VCSEL of FIG. 7 and the prior art VCSEL measured at room temperature.

FIG. 10 is a L-I-V curve of the VCSEL of FIG. 7 and the prior art VCSEL measured at high temperature.

### DESCRIPTION OF THE EMBODIMENTS

The embodiment of the present disclosure is described in detail below with reference to the drawings and element symbols, such that persons skilled in the art is able to implement the present application after understanding the specification of the present disclosure.

Specific examples of components and arrangements are described below to simplify the present disclosure. These are, of course, merely examples and they are not intended to limit the scope of the present disclosure. In the present disclosure, for example, when a layer formed above or on another layer, it may include an exemplary embodiment in which the layer is in direct contact with the another layer, or it may include an exemplary embodiment in which other devices or epitaxial layers are formed between thereof, such that the layer is not in direct contact with the another layer. In addition, repeated reference numerals and/or notations may be used in different embodiments, these repetitions are only used to describe some embodiments simply and clearly, and do not represent a specific relationship between the different embodiments and/or structures discussed.

Further, spatially relative terms, such as “underlying,” “below,” “lower,” “overlying,” “above,” “upper” and the like, may be used herein for ease of description to describe one device or feature's relationship to another device(s) or feature(s) as illustrated in the figures and/or drawings. The spatially relative terms are intended to encompass different orientations of the device in use or operation in addition to the orientation depicted in the figures and/or drawings.

Moreover, certain terminology has been used to describe embodiments of the present disclosure. For example, the terms “one embodiment,” “an embodiment,” and “some embodiments” mean that a particular feature, structure or characteristic described in connection with the embodiment is included in at least one embodiment of the present disclosure. Therefore, it is emphasized and should be appreciated that two or more references to “an embodiment” or “one embodiment” or “an alternative embodiment” in various portions of the present disclosure are not necessarily all referring to the same embodiment.

Furthermore, the particular features, structures or characteristics may be combined in any suitable manner in one or more embodiments of the present disclosure. Further, for the terms “including”, “having”, “with”, “wherein” or the foregoing transformations used herein, these terms are similar to the term “comprising” to include corresponding features.

In addition, a “layer” may be a single layer or a plurality of layers; and “a portion” of an epitaxial layer may be one layer of the epitaxial layer or a plurality of adjacent layers.

In the prior art, the laser diode can be optionally provided with a buffer layer according to actual needs, and in some embodiments, the materials of the buffer and the substrate may be the same. Whether the buffer is provided is not substantially related to the technical characteristics to be described in the following embodiments and the effects to be provided. Accordingly, for the sake of a brief explanation, the following embodiments are only described with a laser diode having a buffer layer, and no further description is given to a laser without a buffer layer; that is, the following embodiments can also be applied by replacing a laser diode without a buffer.

### Embodiment 1-1

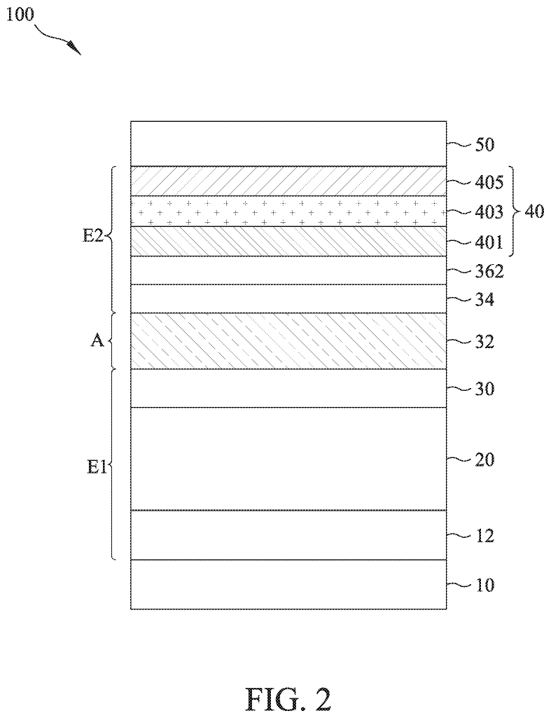

As shown in FIG. 2, the high-power VCSEL 100 includes a GaAs substrate 10, a first epitaxial region E1, an active region A, a second epitaxial region E2 and an ohmic contact layer 50. The first epitaxial region E1 includes a lower DBR layer 20. The first epitaxial region E1 may further include a buffer layer 12 and a first lower spacer layer 30, but not limited thereto. The active region A includes an active layer 32. The second epitaxial region E2 includes an upper DBR layer 40. The second epitaxial region E2 may further include a first upper spacer layer 34 and an oxidation layer 362, but not limited thereto.

The high-power VCSEL referred to in the present disclosure means that the slope efficiency (SE) of the VCSEL is approximately between 0.6 and 6 W/A, wherein the slope efficiency can be 0.65, 0.7, 0.75, 0.8, 0.85, 0.9, 0.95, 1.0, 1.05, 1.1, 1.15, 1.2, 1.5, 1.8, 2.1, 2.4, 2.7, 3, 3.5, 4, 5. The high-power VCSEL can be a top-emitting type VCSEL or a bottom-emitting type VCSEL.

Referring to FIG. 2, each epitaxial layer in the first epitaxial region E1 is made of a N-type material.

As shown in FIG. 2, firstly, the P-type first upper spacer layer 34, the P-type oxidation layer 362 and a P-type epitaxial layer 401 are epitaxially grown on the active layer 32 in sequence. Subsequently, a tunnel junction 403 is epitaxially grown on the P-type epitaxial layer 401. After that, an N-type epitaxial layer 405 and an N-type ohmic contact layer 50 are epitaxially grown on the tunnel junction 403. Referring to FIG. 2, the upper DBR layer 40 includes a PN junction composed of a P-type epitaxial layer 401, the tunnel junction 403 and the N-type epitaxial layer 405. The P-type first upper spacer layer 34, the P-type oxidation layer 362 and the P-type epitaxial layer 401 are all P-type doped, and can be regarded as a P-type epitaxial layer of the PN junction. Similarly, the N-type epitaxial layer 405 and the N-type ohmic contact layer 50 can be regarded as an N-type epitaxial layer of the PN junction.

In one embodiment, the number of P-type epitaxial layers 401 or the number of N-type epitaxial layers 405 can be one or more layers.

It is worth noting whether the oxidation layer 362 or the first upper spacer layer 34 is configured or not, or the number and position of the oxidation layer or the spacer layer in the second epitaxial region E2 is determined in accordance with the performance of the VCSEL, and is not limited to this embodiment. For example, if the second epitaxial region E2 of FIG. 2 is not provided with the P-type oxidation layer 362 and the P-type epitaxial layer 401, the first upper spacer layer 34 can be used as the P-type epitaxial layer of the PN junction. As such, the tunnel junction 403 is directly formed on the first upper spacer layer 34, and the N-type upper DBR layer 40 is formed on the tunnel junction 403.

In a preferred embodiment, the oxidation layer provided in the second epitaxial region E2 is P-type, as shown in FIG. 2.

### Embodiment 1-2

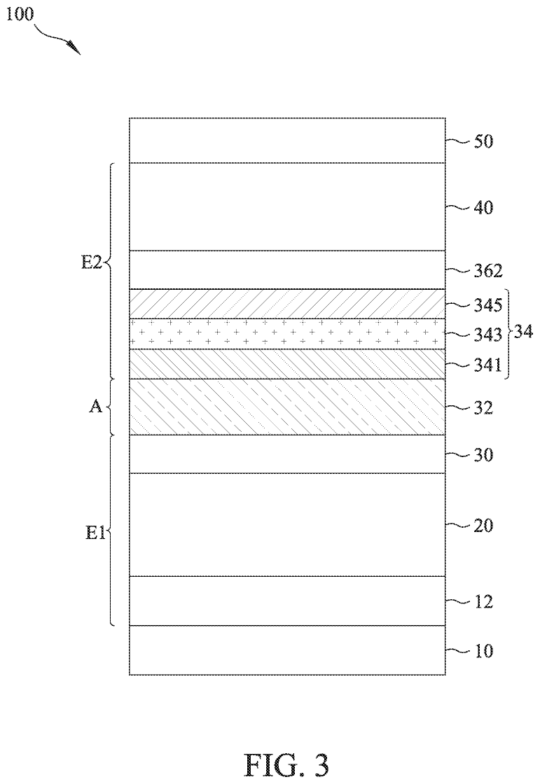

In FIG. 3, each epitaxial layer in the first epitaxial region E1 is an N-type material.

Referring to FIG. 3, firstly, a P-type epitaxial layer 341 is epitaxially grown on the active layer 32. Secondly, a tunnel junction 343 is epitaxially grown on the P-type epitaxial layer 341. After that, an N-type epitaxial layer 345, an N-type oxidation layer 362 and an N-type upper DBR layer 40 are epitaxially grown on the tunnel junction 343 in sequence. As shown in FIG. 3, the first upper spacer layer 34 includes a PN junction composed of the P-type epitaxial layer 341, the tunnel junction 343 and the N-type epitaxial layer 345.

### Embodiment 1-3

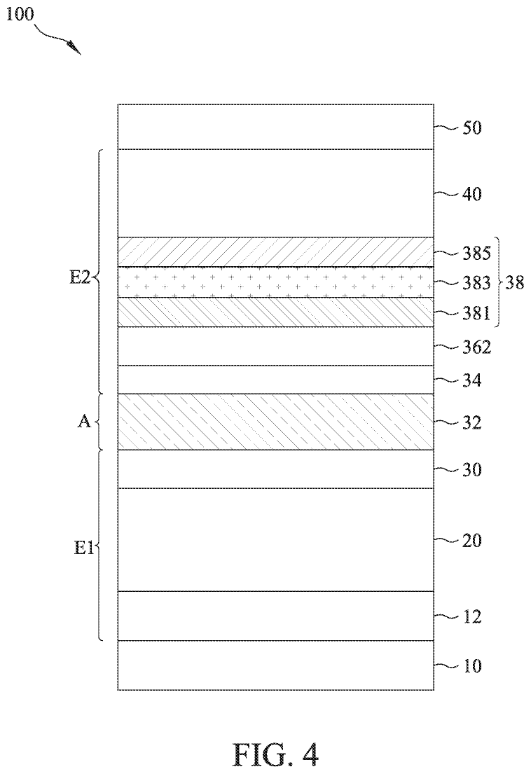

According to FIG. 4, firstly, a P-type first upper spacer layer 34, a P-type oxidation layer 362 and a P-type epitaxial layer 381 are epitaxially grown on the active layer 32 in sequence. Subsequently, a tunnel junction 383 is epitaxially grown on the P-type epitaxial layer 381. After that, an N-type epitaxial layer 385 and an N-type upper DBR layer 40 are epitaxially grown on the tunnel junction 383 in sequence. As shown in FIG. 4, the second upper spacer layer 38 includes a PN junction composed of the P-type epitaxial layer 381, the tunnel junction 383 and the N-type epitaxial layer 385.

In FIG. 4, although the second epitaxial region E2 includes relatively more epitaxial layers (i.e., the first upper spacer layer 34, the oxidation layer 362, the second upper spacer layer 38 and the upper DBR layer). However, as the bulk upper DBR layer is N-type. Consequently, compared with the upper epitaxial region where each layer is a P-type epitaxial layer in the prior art, the total resistance of epitaxial layer materials in the second epitaxial region E2 is significantly less. Accordingly, the output power and performance of the VCSEL have been significantly improved or enhanced. In addition, the second epitaxial region E2 may also be provided with epitaxial layer(s) with different functions so as to further improve the reliability, ruggedness, output power or performance of the VCSEL.

On the other hand, when the resistance of the second epitaxial region E2 is small, the current distribution in the second epitaxial region will be more uniform such that the divergence angle of the laser light emitted by the VCSEL will be relatively small, or the beam profile of the laser light emitted by the VCSEL is closed to or meets the required specific light forming such as Gaussian distribution.

Moreover, compared with the prior art including the upper epitaxial region where each layer is a P-type epitaxial layer, the second epitaxial region E2 including a PN junction has a lower light absorption, that is, the second epitaxial region E2 absorbs less thermal energy of light such that the temperature of the second epitaxial region E2 is lower. Additionally, the second epitaxial region E2 having the PN junction has better thermal conductivity, and the thermal energy in part of the active region is indirectly dissipated through the second epitaxial region E2. Therefore, the output power and performance of the VCSEL have been significantly improved or enhanced.

Embodiments 1-1 to 1-3 respectively enumerate one or more epitaxial layers of the spacer layer or DBR layer as the P-type epitaxial layer(s) of the PN junction, but not limited thereto. If the other epitaxial layers on the active region are P-type, the other epitaxial layers may be used as the P-type epitaxial layers of the PN junction.

### Embodiment 2-1

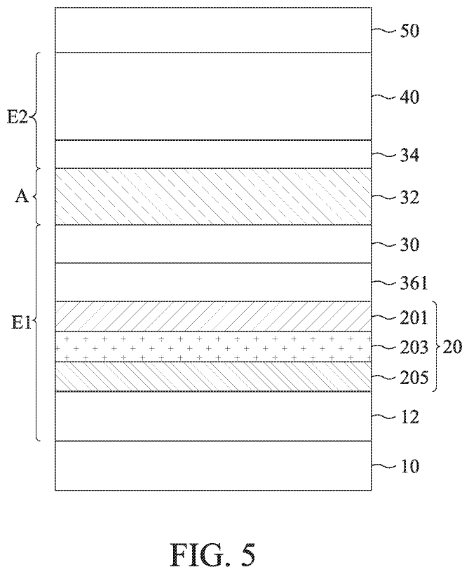

In FIG. 5, each epitaxial layer in the second epitaxial region (not shown) is an N-type material.

Referring to FIG. 5, firstly, an N-type buffer layer 12 and an N-type epitaxial layer 205 are epitaxially grown on the substrate 10 in sequence. Subsequently, a tunnel junction is epitaxially grown on the N-type epitaxial layer 205. After that, a P-type epitaxial layer 201, a P-type oxidation layer 361 and a P-type first lower spacer layer 30 are epitaxially grown on the tunnel junction 203 in sequence. As shown in FIG. 5, the lower DBR layer 20 includes a PN junction composed of the N-type epitaxial layer 205, the tunnel junction 203 and the P-type epitaxial layer 201. Since the P-type epitaxial layer 201, the P-type oxidation layer 361 and the P-type first lower spacer layer 30 are all P-type doped, they can be regarded as P-type epitaxial layers of the PN junction. Similarly, the N-type buffer layer 12 and the N-type epitaxial layer 205 can also be regarded as N-type epitaxial layers of the PN junction.

It is worth noting whether the oxidation layer 361 or the P-type first lower spacer layer 30 is configured or not, or the number and position of the oxidation layer or the lower spacer layer in the first epitaxial region are determined according to the performance of the VCSEL, but not limited thereto. If the P-type epitaxial layer 201 and the P-type oxidation layer 361 are not provided in FIG. 5, the first lower spacer layer 30 can be used as a P-type epitaxial of the PN junction, that is, the first lower spacer layer 30 is disposed between the tunnel junction 203 and the active region A.

### Embodiment 2-2

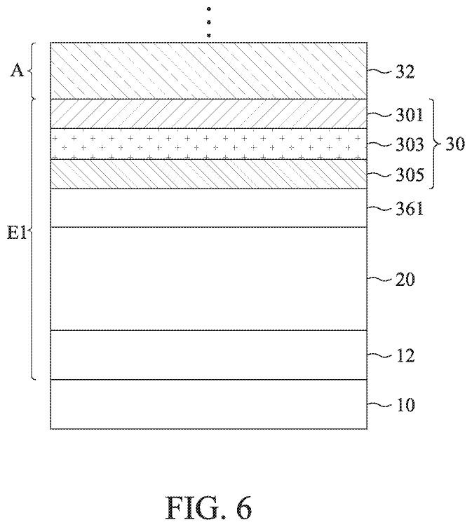

In FIG. 6, each epitaxial layer in the second epitaxial region (not shown) is an N-type material.

Referring to FIG. 6, firstly, an N-type buffer layer 12, an N-type lower DBR layer 20, an N-type oxidation layer 361 and an N-type epitaxial layer 305 are epitaxially grown on the substrate 10 in sequence. Subsequently, a tunnel junction 303 is epitaxially grown on the N-type epitaxial layer 305. After that, a P-type epitaxial layer 301 is epitaxially grown on the tunnel junction 303. In addition, an active layer 32 is epitaxially grown on the P-type epitaxial layer 301. As shown in FIG. 6, the first lower spacer layer 30 includes a PN junction composed of the N-type epitaxial layer 305, the tunnel junction 303 and the P-type epitaxial layer 301.

### Embodiment 2-3

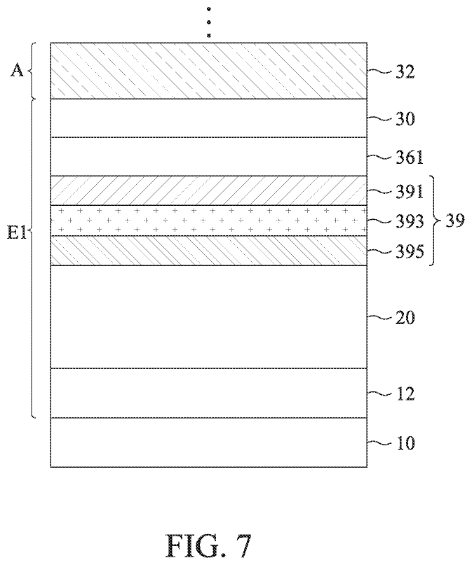

In FIG. 7, each epitaxial layer in the second epitaxial region (not shown) is an N-type material.

Referring to FIG. 7, first, an N-type buffer layer 12, an N-type lower DBR layer 20 and an N-type epitaxial layer 395 are epitaxially grown on the substrate 10 in sequence. Subsequently, a tunnel junction 393 is epitaxially grown on the N-type epitaxial layer 395. After that, a P-type epitaxial layer 391, a P-type oxidation layer 361 and a P-type first lower spacer layer 30 are sequentially formed on the tunnel junction 393. As shown in FIG. 7, the second lower spacer layer 30 includes a PN junction composed of the N-type epitaxial layer 395, the tunnel junction 393 and the P-type epitaxial layer 391.

In FIG. 7, although the first epitaxial region E1 includes relatively more epitaxial layers (i.e., the P-type first lower spacer layer 30, the oxidation layer 361, the second lower spacer layer 39 and the lower DBR layer 20). Since the lower DBR layer 20 is N-type, the total resistance of epitaxial layer materials of the first epitaxial region E1 will not be too large, the light absorption is also lower, and the thermal conductivity is better. As such, the first epitaxial region E1 can be further provided with an epitaxial layer that helps to improve the performance of the VCSEL so as to further improve the output power, power conversion efficiency (PCE) or performances of the VCSEL.

In some embodiments, one or more oxidation layers, spacers and other appropriate epitaxial layers are respectively provided in the first epitaxial region and the second epitaxial region. The number and location of the oxidation layers and the spacer layers are determined in accordance with the required performance of the VCSEL.

Take the upper DBR layer 40 with a PN junction as an example. When the laser diode is forward biased, although the hole mobility of the P-type epitaxial layer in the upper DBR layer 40 is slower, the electron mobility of the N-type epitaxial layer is faster. Hence, the current distribution of the second epitaxial region E2 will become more uniform such that the divergence angle of the laser light generated by the VCSEL is smaller, or the beam profile of the VCSEL can conform to a predetermined specific beam profile (for example, the light intensity in the center of the light forming is relatively similar to the surrounding light intensity).

When the doping concentrations of the P-type epitaxial layer and the N-type epitaxial layer are the same, the electron mobility of the N-type epitaxial layer in the upper DBR layer 40 is fast such that the resistance of the material of the N-type DBR layer 405 is small. Therefore, the doping concentration of the N-type DBR layer 405 can be appropriately reduced. As a consequence, without increasing the resistance of the material of the upper DBR layer 40, the absorption of light by the upper DBR layer 40 is further reduced to increase the light output power of the VCSEL.

When the lower DBR layer, the first upper spacer layer, the second upper spacer layer, the first lower spacer layer or the second lower spacer layer includes a PN junction, the light output power and power conversion efficiency (PCE) of the VCSEL can also be improved.

In some embodiments, when the ohmic contact layer contains N-type GaAs, N-type InGaAs, N-type GaAsSb, N-type InAlGaAs, N-type InGaAsSb or any combination of the above materials, the resistance of the material of the ohmic contact layer can be reduced, and the current spreading in the second epitaxial region is better, or the resistance of the VCSEL can be further reduced.

In some embodiments, the doping element of the ohmic contact layer is selected from the group consisting of Si, Te and Se. As a result, the resistance of the material of the ohmic contact layer can be reduced, the current is more uniformly distributed in the second epitaxial region, or the resistance of the VCSEL can be further reduced.

### Embodiment 3

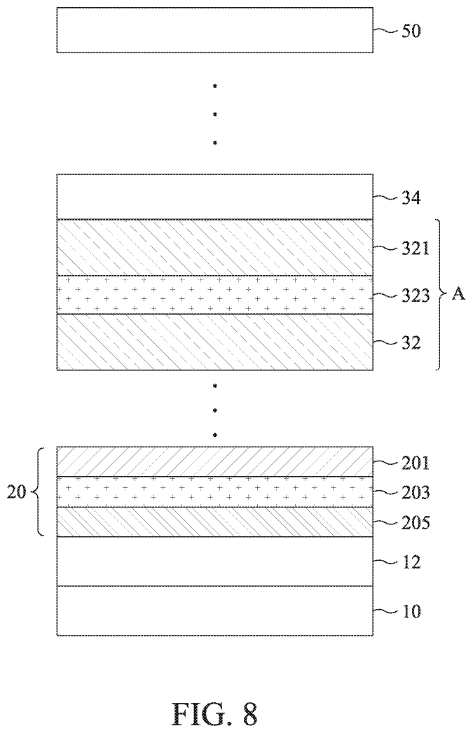

As shown in FIG. 8, the active region A includes two active layers 32 and 321 and a tunnel junction 323 between two active layers 32 and 321.

In some embodiments, a PN junction (hereinafter referred to as another PN junction) may also be provided between two active layers 32 and 321, that is, the N-type epitaxial layer (not shown in FIG. 8) and the P-type epitaxial layer (not shown in FIG. 8) are further arranged above and below the tunnel junction 323 in FIG. 8. It is worth noting that when another PN junction is disposed in the active region, the position of the P-type epitaxial layer is not limited, that is, the P-type epitaxial layer may be disposed above or below the tunnel junction 323. The number of active layers may be one or more than three.

In some embodiments, an oxidation layer and/or a spacer layer is further provided between two active layers.

In some embodiments, a tunnel junction may be provided between any two adjacent active layers in the active region. For example, if the active region contains three active layers, a tunnel junction is arranged between the uppermost active layer and the middle active layer, and a tunnel junction is also disposed between the middle active layer and the lowermost active layer.

In one embodiment, a tunnel junction and an oxidation layer may be provided between any two adjacent active layers in the active region. For example, if the active region contains three active layers, a tunnel junction and an oxidation layer are arranged between the upmost active layer and the middle active layer, and a tunnel junction and an oxidation layer are also provided between the middle active layer and the lowermost active layer.

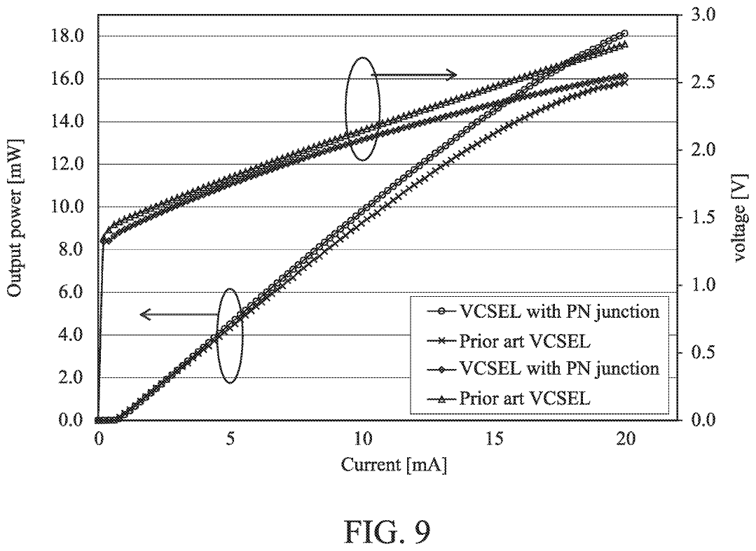

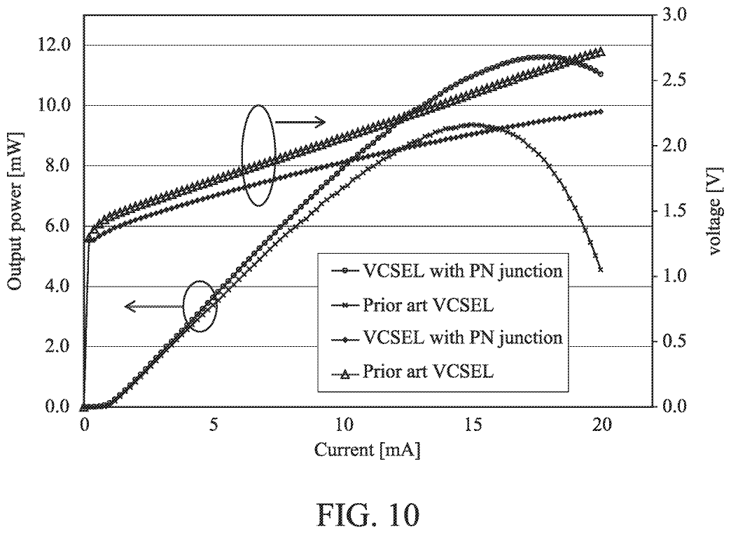

Referring to FIGS. 9 and 10, FIGS. 9 and 10 are the L-I-V curves of the VCSEL of FIG. 7 and the prior art VCSEL measured at room temperature and high temperature, respectively. The aforesaid room temperature and high temperature are 25° C. and 85° C., respectively.

In the VCSEL of the embodiment of the present disclosure, as shown in FIG. 7 (referring to Embodiment 2-3), the second lower spacer layer 39 in the first epitaxial region E1 includes a PN junction, and the second epitaxial region is N-type. Except that the total reflectivity of the prior art VCSEL and the total reflectivity of the upper DBR layer of the VCSEL of FIG. 7 are approximately similar, the total reflectivity of the prior art VCSEL and the total reflectivity of the lower DBR layer of the VCSEL of FIG. 7 are also approximately similar. In addition, the oxide layers of both the prior art and FIG. 7 have current confinement optical apertures (OAs) with roughly the same diameter. The main difference between the structure of the prior art VCSEL and the VCSEL of FIG. 7 is that the epitaxial layers of the second epitaxial region of the prior art VCSEL are all P-type; only some epitaxial layers in the first epitaxial region of the VCSEL of FIG. 7 are P-type, and other epitaxial layers (including the lower DBR layer) are N-type.

According to the L-I-V curves of FIGS. 9 and 10, it can be found that the voltage (Vf) of the VCSEL in FIG. 7 is less than the voltage (Vf) of the prior art VCSEL at the current values while the output power of the VCSEL in FIG. 7 is greater than the output power of the prior art VCSEL at a constant current value. It can be seen that since the VCSEL with the PN junction includes more N-type epitaxial layers, the resistance of the VCSEL is smaller and the output power of the VCSEL is larger.

When the temperature is 25° C., the output power of the VCSEL in FIG. 7 and the output power of the prior art VCSEL are 11.7 mW and 11 mW at 12 mA, respectively, as shown in FIG. 9. When the temperature increases from 25° C. to 85° C., the output power of the VCSEL in FIG. 7 drops slightly from 11.7 mW to 9.34 mW (at 12 mA) while the output power of the prior art VCSEL drops from 11 mW to 8.4 mW, as shown in FIG. 10. It can be seen that since the VCSEL with the PN junction includes more N-type epitaxial layers such that the heat dissipation of the VCSEL is obviously better; that is, the VCSEL with the PN junction has better high temperature performance.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A high-power vertical cavity surface emitting laser diode (VCSEL), comprising:
an N-type first epitaxial region located on a substrate;
an active region located on the N-type first epitaxial region, wherein the active region includes one or more active layers; and
a second epitaxial region located on the active region, wherein the second epitaxial region includes a PN junction, the PN junction includes at least one P-type epitaxial layer, a tunnel junction and at least one N-type epitaxial layer, the tunnel junction is located between the at least one P-type epitaxial layer and the at least one N-type epitaxial layer,
wherein the at least one P-type epitaxial layer is close to the active region, and the at least one P-type epitaxial layer is between the active region and the at least one N-type epitaxial layer.

2. The high-power VCSEL as claimed in claim 1, wherein the high-power VCSEL has a slope efficiency of 0.6 Watts/Amp or greater.

3. The high-power VCSEL as claimed in claim 1, wherein the high-power VCSEL is a top-emitting VCSEL or a bottom-emitting VCSEL.

4. The high-power VCSEL as claimed in claim 1, wherein the second epitaxial region includes an upper DBR layer or a spacer layer, and the upper DBR layer or the spacer layer is the at least one P-type epitaxial layer.

5. The high-power VCSEL as claimed in claim 1, wherein the second epitaxial region includes an upper DBR layer or a spacer layer, and the upper DBR layer or the spacer layer includes the PN junction.

6. The high-power VCSEL as claimed in claim 1, wherein the second epitaxial region includes a spacer layer and an oxidation layer, and the spacer layer is between the active region and the oxidation layer.

7. The high-power VCSEL as claimed in claim 1, wherein the second epitaxial region includes an oxidation layer, and the PN junction is on or beneath the oxidation layer.

8. The high-power VCSEL as claimed in claim 1, further comprising an ohmic contact layer, located on the second epitaxial region, wherein the ohmic contact layer comprises a N-type material selected from the group consisting of GaAs, InGaAs, GaAsSb, InAlGaAs and InGaAsSb.

9. The high-power VCSEL as claimed in claim 1, further comprising an N-type ohmic contact layer, located on the second epitaxial region, wherein the N-type ohmic contact layer further comprises a doping element selected from the group consisting of Si, Te and Se.

10. The high-power VCSEL as claimed in claim 1, wherein the active region further includes a tunnel junction or another PN junction, and the tunnel junction or the another PN junction is disposed between two active layers of the more active layers.

11. The high-power VCSEL as claimed in claim 1, wherein the active region further includes an oxidation layer, and the oxidation layer is disposed between two active layers of the more active layers.

12. The high-power VCSEL as claimed in claim 1, wherein the active region further includes a plurality of oxidation layers and a plurality of tunnel junctions, and at least one tunnel junction and at least one oxidation layer are disposed between each two adjacent active layers in the active region.

13. A high-power vertical cavity surface emitting laser diode (VCSEL), comprising:
a first epitaxial region, located on a substrate, wherein the first epitaxial region includes a PN junction, the PN junction includes at least one P-type epitaxial layer, a tunnel junction and at least one N-type epitaxial layer, and the tunnel junction is located between the at least one P-type epitaxial layer and the at least one N-type epitaxial layer;
an active region, located on the first epitaxial region, wherein the active region includes one or more active layers; and
an N-type second epitaxial region, located on the active region;
wherein the at least one P-type epitaxial layer is close to the active region, and the at least one N-type epitaxial layer is close to the substrate.

14. The high-power VCSEL as claimed in claim 13, wherein the high-power VCSEL has a slope efficiency of 0.6 Watts/Amp or greater.

15. The high-power VCSEL as claimed in claim 13, wherein the high-power VCSEL is a top-emitting VCSEL or a bottom-emitting VCSEL.

16. The high-power VCSEL as claimed in claim 13, wherein the first epitaxial region includes a lower DBR layer or a spacer layer, and the lower DBR layer or the spacer layer is the at least one P-type epitaxial layer.

17. The high-power VCSEL as claimed in claim 13, wherein the first epitaxial region includes a lower DBR layer or a spacer layer, and the lower DBR layer or the spacer layer includes the PN junction.

18. The high-power VCSEL as claimed in claim 13, wherein the first epitaxial region further includes a spacer layer and an oxidation layer, and the spacer layer is between the active region and the oxidation layer.

19. The high-power VCSEL as claimed in claim 13, wherein the first epitaxial region further includes an oxidation layer, and the PN junction is beneath or on the oxidation layer.

20. The high-power VCSEL as claimed in claim 13, further comprising an ohmic contact layer, located on the second epitaxial region, wherein the ohmic contact layer comprises an N-type material selected from the group consisting of GaAs, InGaAs, GaAsSb, InAlGaAs and InGaAsSb.

21. The high-power VCSEL as claimed in claim 13, wherein further comprising an N-type ohmic contact layer, located on the second epitaxial region, wherein the N-type ohmic contact layer further comprises a doping element selected from the group consisting of Si, Te and Se.

22. The high-power VCSEL as claimed in claim 13, wherein the active region further includes a tunnel junction or another PN junction, and the tunnel junction or the another PN junction is disposed between two active layers of the more active layers.

23. The high-power VCSEL as claimed in claim 13, wherein the active region further includes an oxidation layer, and the oxidation layer is disposed between two active layers of the more active layers.

24. The high-power VCSEL as claimed in claim 13, wherein the active region further includes a plurality of oxidation layers and a plurality of tunnel junctions, and at least one tunnel junction and at least one oxidation layer are disposed between each two adjacent active layers in the active region.
